(19) United States
(12) Patent Application Publication
(10) Pub. No.: US 2015/0189760 A1
(43) Pub. Date: Jul. 2, 2015

(54) FLEXIBLE PRINTED CIRCUIT BOARD AND METHOD FOR MANUFACTURING SAME

(71) Applicants: FuKui Precision Component (Shenzhen) Co., Ltd., Shenzhen (CN); Zhen Ding Technology Co., Ltd., Tayuan (TW)

(72) Inventors: MING-JAAN HO, New Taipei (TW); XIAN-QIN HU, Shenzhen (CN); FU-YUN SHEN, Shenzhen (CN); ZHI-TIAN WANG, Shenzhen (CN)

(21) Appl. No.: 14/583,120

(22) Filed: Dec. 25, 2014

(30) Foreign Application Priority Data
Dec. 26, 2013 (CN) 201310729681.0

(51) Int. Cl. H05K 3/06; G03F 7/20; H05K 1/11; H05K 1/02; H05K 1/03

(52) U.S. Cl. CPC H05K 3/06; H05K 1/028; H05K 1/0326; H05K 1/115; G03F 7/20; H05K 2201/0108

(57) ABSTRACT

A flexible printed circuit board (PCB) used for near field communication and a method for manufacturing the flexible PCB are provided. The flexible PCB includes an insulating layer; a first conductive circuit layer adhered on a surface of the insulating layer, the first conductive circuit layer includes at least one first conductive circuit arranged as spiral-shaped and defines a plurality of first spaces; a first resin layer is adhered on a surface of the insulating layer and fills the first spaces; and a first cover layer adhered on a surface of the first resin layer and a surface of the first conductive circuit layer away from the insulating layer.

### FIELD

The present disclosure relates to printed circuit board (PCB).

### BACKGROUND

Near field communication (NFC) is a form of contactless communication between devices like smart phones or tablets. Contactless communication allows a user to wave the smart phone over a NFC compatible device to send information with no need to touch the devices together or go through multiple steps setting up a connection. A flexible printed circuit board is used in producing this function.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a flow chart of a method for manufacturing a flexible printed circuit board according to an embodiment.

FIG. 2 is a cross-sectional view of a copper-clad laminate according to an embodiment.

FIG. 3 illustrates that a plurality of conductive holes are formed in the copper-clad laminate of FIG. 2.

FIG. 4 illustrates that conductive circuit layers are formed by etching copper foils of copper-clad laminate in FIG. 3 in a top view.

FIG. 5 illustrates that conductive circuit layers are formed by etching copper foils of copper-clad laminate in FIG. 3 in a bottom view, to obtain a printed circuit substrate.

FIG. 6 is a cross-sectional view along a V-V line in FIG. 4.

FIG. 7 illustrates that resin is filled into spaces defined by the conductive circuit layers in FIG. 6.

FIG. 8 illustrates that cover layers are respectively formed on the opposite side of the printed circuit substrate of FIG. 7.

FIG. 9 is a cross-sectional view along a VIII-VIII line in FIG. 8.

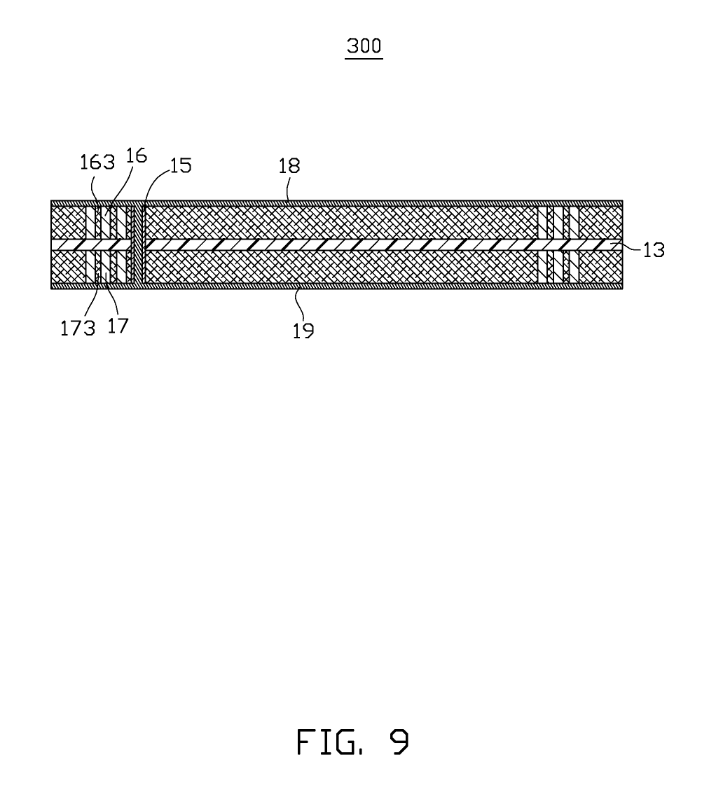

FIG. 10 is a partial cross-sectional view along an IX-IX line in FIG. 8.

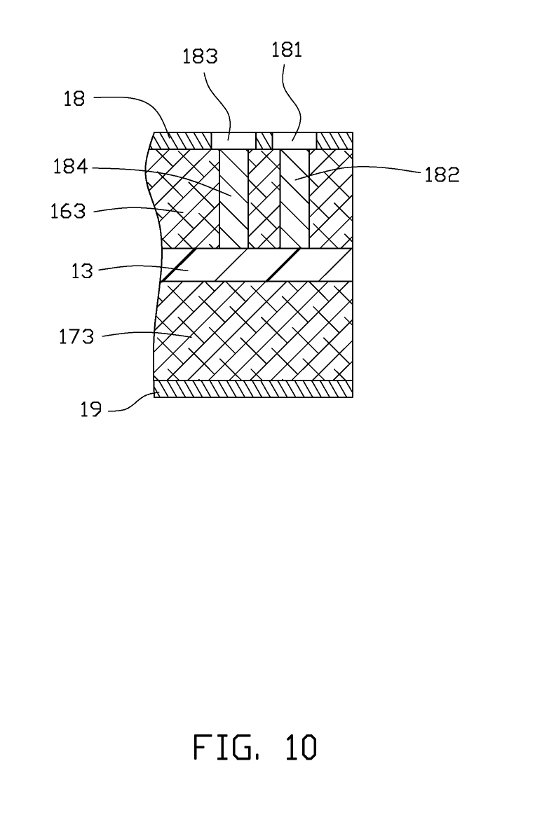

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

A method for manufacturing a flexible printed circuit board used for near field communication, includes: forming a printed circuit substrate having a first conductive circuit layer, including at least one first conductive circuit 161 arranged as spiral-shaped and defining a plurality of first spaces 162, and an insulating layer adhered to the first conductive circuit layer; filling the plurality of first spaces with resin, to form a first resin layer adhered to a surface of the insulating layer; and forming a first cover layer on a surface of the first resin layer and a surface of the first conductive circuit layer away from the insulating layer.

A flexible printed circuit board used for near field communication, includes: an insulating layer; a first conductive circuit layer adhered on a surface of the insulating layer, the first conductive circuit layer includes at least one first conductive circuit arranged as spiral-shaped and defines a plurality of first spaces; a first resin layer adhered on a surface of the insulating layer, the first resin layer fills the first spaces; and a first cover layer adhered on a surface of the first resin layer and a surface of the first conductive circuit layer away from the insulating layer.

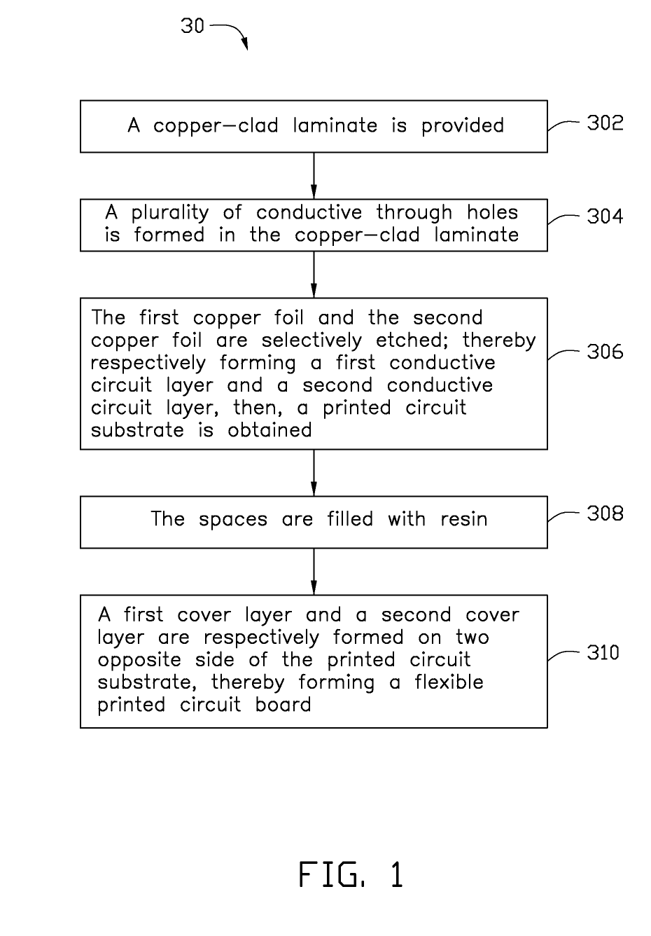

Referring to FIG. 1, a flowchart is presented in accordance with an example embodiment. The example method 30 is provided by way of example, as there are a variety of ways to carry out the method. The method 30 described below can be carried out using the configurations illustrated in FIG. 1, for example, and various elements of these figures are referenced in explaining example method 30. Each block shown in FIG. 1 represents one or more processes, methods, or subroutines, carried out in the exemplary method 30. Additionally, the illustrated order of blocks is by example only and the order of the blocks can change. The exemplary method 30 can begin at block 302.

At block 302, a copper-clad laminate including a first copper foil and a second copper foil is provided.

At blocks 304, a plurality of conductive through holes is formed in the copper-clad laminate.

At blocks 306, the first copper foil and the second copper foil are selectively etched; thereby respectively forming a first conductive circuit layer and a second conductive circuit layer, the first and second conductive circuit layer define a plurality of spaces, thereby forming a printed circuit substrate.

At blocks 308, the spaces are filled with resin.

At blocks 310, a first cover layer and a second cover layer are respectively formed on two opposite sides of the printed circuit substrate, thereby forming a flexible printed circuit board.

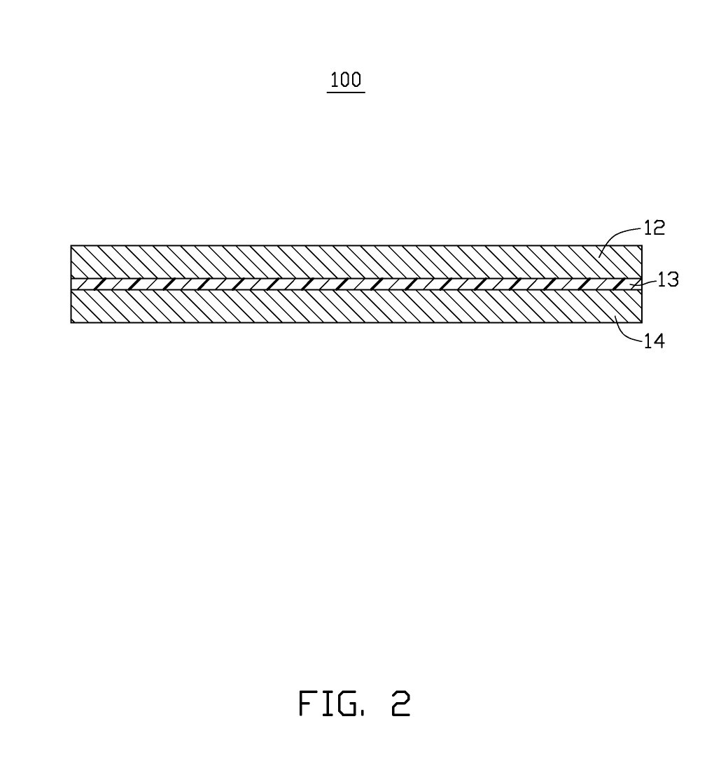

FIG. 2 illustrates that a copper-clad laminate 100 includes a first copper foil 12, an insulating layer 13, and a second copper foil 13. The insulating layer 13 is adhered between the first copper foil 12 and the second copper foil 13. In this embodiment, thicknesses of the first copper foil 12 and the second copper foil 13 are all about 70 micrometers. The insulating layer 13 is made of flexible material, such as polyimide (PI), polyethylene terephtalate (PET), or Polyethylene naphthalate (PEN). In other embodiments, the second copper foil 13 can be omitted.

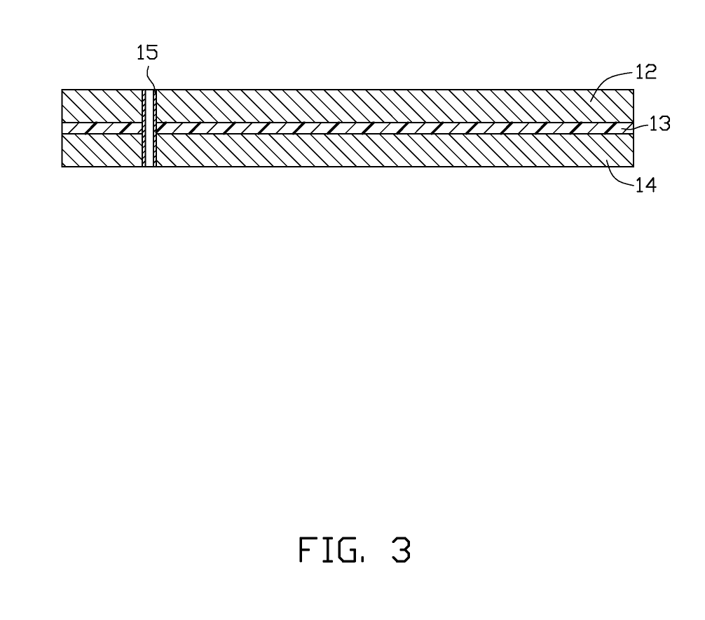

FIG. 3 illustrates that a plurality of conductive through holes 15 is formed in the copper-clad laminate 100. The conductive through holes 15 are electrically connected to the first copper foil 12 and the second copper foil 13. In this embodiment, a number of the conductive through holes 15 is two. In this embodiment, the conductive through holes 15 can be formed by the following steps. First, a plurality of through holes 15 is formed in the copper-clad laminate 100 by a mechanical drilling process or a laser drilling process. Second, a conductive layer is formed on the inner walls of the through holes, to obtain the conductive through holes 15.

In other embodiments, the conductive through holes 15 can be omitted when the second copper foil 13 of the copper-clad laminate 100 is omitted.

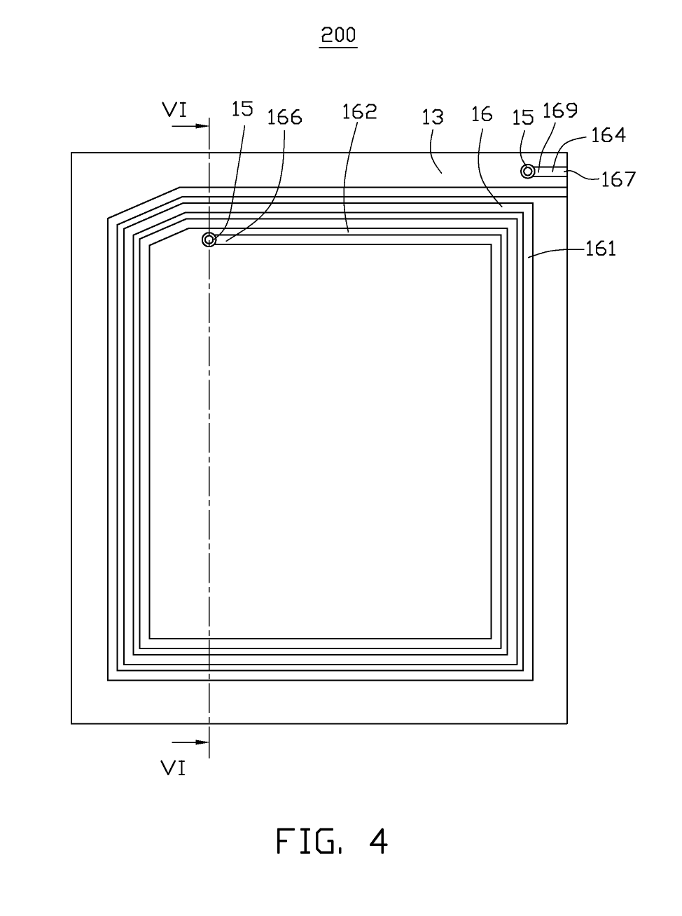

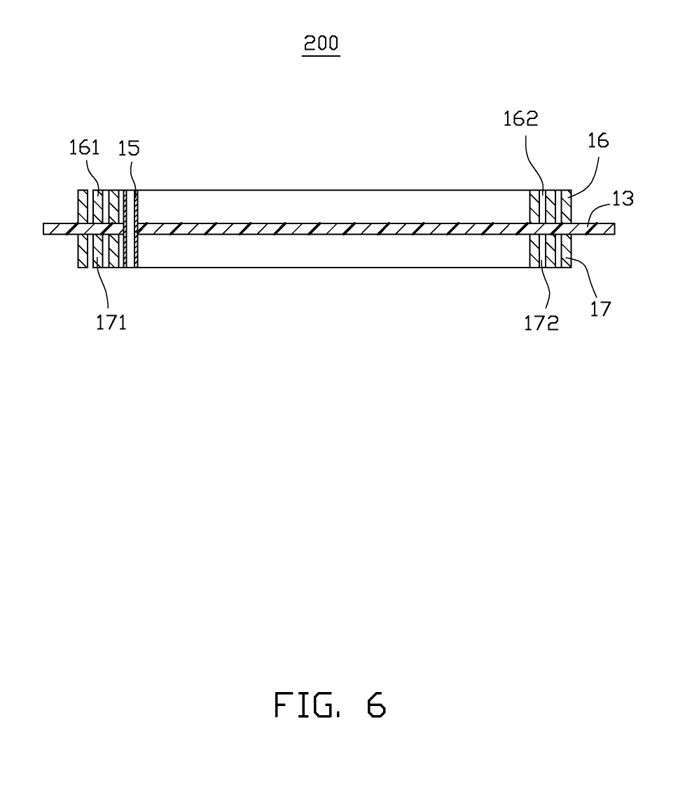

FIGS. 4-6 illustrate that a first conductive circuit layer 16 and a second conductive circuit layer 17 are formed, and a plurality of conductive through holes 15 electrically connects to the first conductive circuit layer 16 and the second conductive circuit layer 17, thereby forming a printed circuit substrate 200.

In this embodiment, the first conductive circuit layer 16 and the second conductive circuit layer 17 can be formed by a photolithography process and an etching process.

FIG. 4 illustrates that the first conductive circuit layer 16 includes at least one first conductive circuit 161 and a third conductive circuit 164. The first conductive circuit 161 is arranged as spiral-shaped, that is, the first conductive circuit 161 includes a plurality of first windings 165. The first conductive circuit layer 16 defines a plurality of first spaces 162. In this embodiment, the first spaces 162 are defined adjacent to the first conductive circuit 161 and the third conductive circuit 162, such as between each two adjacent first windings 165, between first conductive circuit 161 and a third conductive circuit 164, and etc. The first conductive circuit 161 has an inner end 166 on the inner one of the first windings 165 and a first outer end 167 on the outer one of the first windings 165. The third conductive circuit 164 has a second outer end 168 near to the first outer end 167 and a third outer end 169 opposite to the second outer end 168.

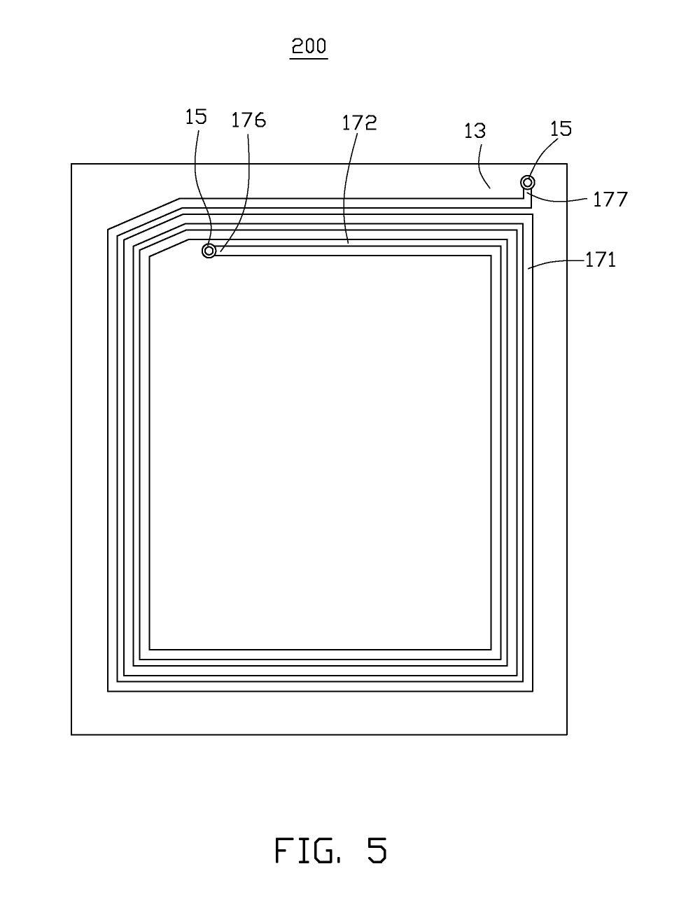

FIG. 5 illustrates that the second conductive circuit layer 17 includes at least one second conductive circuit 171. The second conductive circuit 171 is also arranged as spiral-shaped, that is, the second conductive circuit 161 includes a plurality of second windings 175. The second conductive circuit layer 17 defines a plurality of first spaces 172. In this embodiment, the second spaces 172 are defined adjacent to the second conductive circuit 171, like between each two adjacent second windings 175, and etc. The second conductive circuit 171 has an inner end 176 on the inner one of the second winding 175 and a fourth outer end 177 on the outer one of the second windings 175. The depth of the first spaces 162 and depth of the second spaces 172 are all about 70 micrometers.

FIGS. 4-6 illustrate that in this embodiment, one of the conductive through holes 15 directly connects to the inner end 166 of the first conductive circuit 161 and the inner end 176 of the second conductive circuit 171, and the other conductive through hole 15 directly connects to the third outer end 169 of the third conductive circuit 162 and the fourth outer end 177 of the second conductive circuit 171.

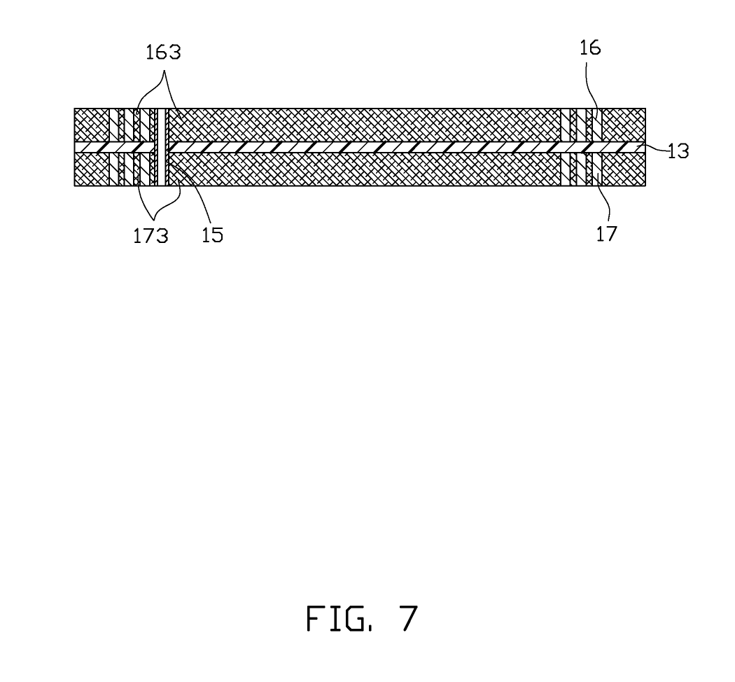

FIG. 7 illustrates that the first spaces 162 are filled with resin, thereby forming a first resin layer 163, and the second spaces 172 are filled with resin, thereby forming a second resin layer 173. The first resin layer 163 is adhered to a surface of the insulating layer 13 away from the second conductive circuit layer 17. The second resin layer 173 is adhered to a surface of the insulating layer 13 away from the first conductive circuit layer 16.

In this embodiment, the resin can be filled in the first spaces 162 and the second spaces 172 by a screen printing process, and then the resin can be cured by a heat curing process, to obtain the first resin layer 163 and the second resin layer 173.

In this embodiment, the first resin layer 163 and the second resin layer 173 can be made of transparent resin, and a light transmittance of first resin layer 163 and the second resin layer 173 can be greater than about 90 percent.

In the embodiment, the first resin layer 163 and the second resin layer 173 can be made of transparent ink without inorganic filler, to obtain a lower dielectric constant. A composition of the transparent ink without inorganic filler is recommended in the following table.

| | | Content | Preferred content |
|---|---|---|---|
| composition | | (wt %) | (wt %) |
| resin | cycloaliphatic epoxide | 28-34% | 31.55% |
| | phenoxyl resin | 10-20% | 12.62% |
| hardener | methylhexahydrophthalic | 22-26% | 23.66% |
| | anhydride (MHHPA) | | |
| solvent | 2-Butoxy ethanol (BCS) | 20-40% | 31.55% |
| defoamer | polyether modified polysiloxane | 0.2-1% | 0.63% |
| total | — | — | 100.0% |

In other embodiments, the first resin layer 163 and the second resin layer 173 can be made of opaque resin with a light transmittance less than 90 percent.

In this embodiment, the resin can be fully filled in the first spaces 162 and the second spaces 172, thereby, a surface of the first resin layer 163 away from the insulating layer 13 is coplanar with a surface of the first conductive circuit layer 16 away from the insulating layer 13, and a surface of the second resin layer 173 away from the insulating layer 13 is coplanar with a surface of the second conductive circuit layer 17 away from the insulating layer 13.

In other embodiments, the resin can be partly filled in the first spaces 162 and the second spaces 172, thereby, a surface of the first resin layer 163 away from the insulating layer 13 is recessed with respect to a surface of the first conductive circuit layer 16 away from the insulating layer 13, and a surface of the second resin layer 173 away from the insulating layer 13 is recessed with respect to a surface of the second conductive circuit layer 17 away from the insulating layer 13.

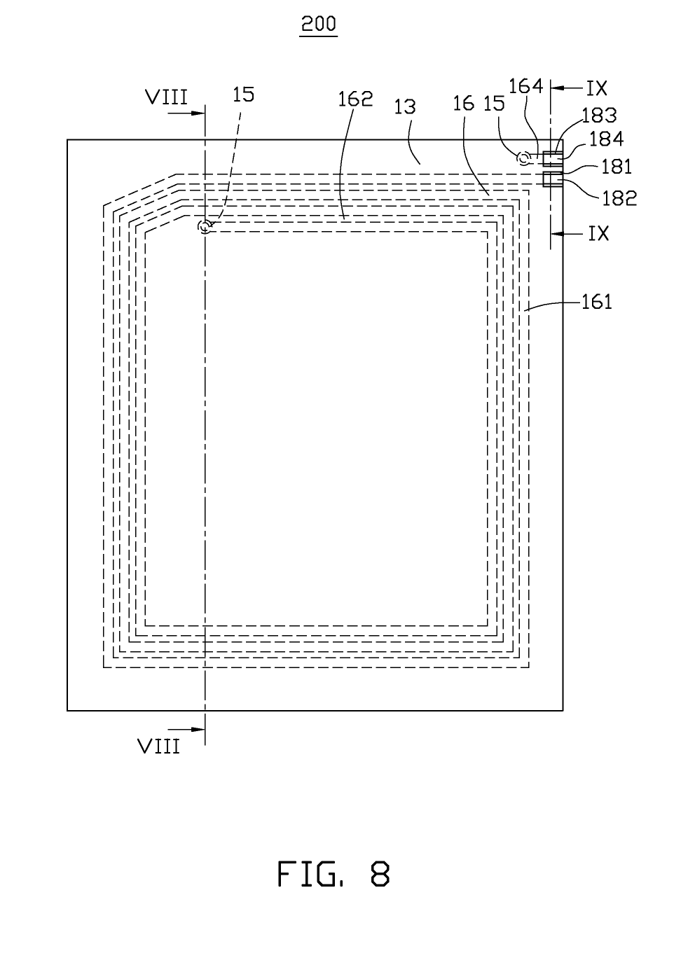

FIG. 8 illustrates that a first cover layer 18 and a second cover layer 19 are formed on two opposite sides of the printed circuit substrate 200, to obtain a flexible printed circuit board 300.

The flexible printed circuit board 300 includes a first cover layer 18, a first conductive circuit layer 16, an insulating layer 13, a second conductive circuit layer 17, and a second cover layer 19. The first conductive circuit layer 16 and the second conductive circuit layer 17 are formed on two opposite sides of the insulating layer 13. The first conductive circuit layer 16 includes at least one first conductive circuit 161 and a third conductive circuit 164. The first conductive circuit 161 is arranged as spiral-shaped. The first conductive circuit layer 16 defines a plurality of first spaces 162. The first conductive circuit 161 has an inner end 166 on the inner one of the first windings 165 and a first outer end 167 on the outer one of the first windings 165. The third conductive circuit 164 has a second outer end 168 near to the first outer end 167 and a third outer end 169 opposite to the second outer end 168. The second conductive circuit layer 17 includes at least one second conductive circuit 171. The second conductive circuit 171 is also arranged as spiral-shaped. The second conductive circuit layer 17 defines a plurality of first spaces 172. The second conductive circuit 171 has an inner end 176 on the inner one of the second winding 175 and a fourth outer end 177 on the outer one of the second windings 175. A depth of the first spaces 162 and a depth of the second spaces 172 are all about 70 micrometers. One of the conductive through holes 15 electrically connects to the inner end 166 of the first conductive circuit 161 and the inner end 176 of the second conductive circuit 171, and the other conductive through hole 15 electrically connects to the third outer end 169 of the third conductive circuit 162 and the fourth outer end 177 of the second conductive circuit 171. The first spaces 162 are filled in with the first resin layer 163, and the second spaces 172 are filled in with the second resin layer 173. The first cover layer 18 and the second cover layer 19 are formed on two opposite sides of the flexible printed circuit substrate 300. The first cover layer 18 covers the first conductive circuit layer 16 and the first resin layer 163. The second cover layer 19 covers the second conductive circuit layer 17 and the second resin layer 173. A first opening 181 and a second opening 183 are defined in the first cover layer 18. A portion of the first outer end 167 of the first conductive circuit 161 is exposed from the first opening 181, to form a first contact pad 182. A portion of the second outer end 168 of the third conductive circuit 162 is exposed from the second opening 183, to form a second contact pad 184. The first contact pad 182 and the second contact pad 184 are configured to connect electronic components.

In this embodiment, the first cover layer 18 and a second cover layer 19 can be photosensitive cover layer in a single layer, and a main composition of the photosensitive cover layer can be polyurethane.

In this embodiment, the first cover layer 18 and the second cover layer 19 can be formed by the following steps. First, surfaces of the printed circuit substrate 200 can be cleaned and roughened by a surface treatment process after forming the first resin layer 163 and the second resin layer 173. Second, a photosensitive cover layer is formed on a surface of the first resin layer 163 and a surface of the first conductive circuit layer 16 away from the insulating layer 13, and another photosensitive cover layer is formed on a surface of the second resin layer 173 and a surface of the second conductive circuit layer 17 away from the insulating layer 13. Third, portions of the two photosensitive cover layers are removed by a photolithography process. Fourth, the two photosensitive cover layers are cured, to obtain the first cover layer 18 and a second cover layer 19.

In other embodiments, the first cover layer 18 and the second cover layer 19 can be non photosensitive cover layers including a film layer and a pressure sensitive adhesive layer, and can be adhered to the printed circuit substrate 200 by pressure.

The first cover layer 18 and the second cover layer 19 can be thinner since they do not need to fill the first spaces 162 and the second spaces 172, it is preferred that the resin fully fills the first spaces 162 and the second spaces 172.

In other embodiments, the first opening 181 and the second opening 183 can be replaced by an opening which exposes the first contact pad 182 and the second contact pad 184 together.

In other embodiments, an oxidation resistance treatment can be processed on surfaces of the first contact pad 182 and the second contact pad 184 after forming the first cover layer 18 and the second cover layer 19, such as a gold plating treatment, or an organic solderability preservative treatment.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method for manufacturing a flexible printed circuit board used for near field communication comprising:
forming a printed circuit substrate having a first conductive circuit layer, comprising at least one first conductive circuit arranged as spiral-shaped and defining a plurality of first spaces, and an insulating layer adhered to the first conductive circuit layer;
filling the plurality of first spaces with resin, to form a first resin layer adhered to a surface of the insulating layer; and
forming a first cover layer on a surface of the first resin layer and a surface of the first conductive circuit layer away from the insulating layer.

2. The method of claim 1, wherein the first resin layer is made of transparent resin, a light transmittance of first resin layer is greater than about 90 percent.

3. The method of claim 2, wherein the first resin layer is made of transparent ink without inorganic filler, the transparent ink without inorganic filler is consist of cycloaliphatic epoxide with a weight percentage of 28% to 34%, phenoxyl resin with a weight percentage of 10% to 20%, methylhexahydrophthalic anhydride with a weight percentage of 22% to 26%, 2-Butoxy ethanol with a weight percentage of 20% to 40%, and polyether modified polysiloxane with a weight percentage of 0.2% to 1%.

4. The method of claim 3, wherein the transparent ink without inorganic filler is consist of cycloaliphatic epoxide with a weight percentage of 31.55%, phenoxyl resin with a weight percentage of 12.62%, methylhexahydrophthalic anhydride with a weight percentage of 23.66%, 2-Butoxy ethanol with a weight percentage of 31.55%, and polyether modified polysiloxane with a weight percentage of 0.63%.

5. The method of claim 1, wherein the resin is fully infilled the first spaces, thereby, a surface of the first resin layer away from the insulating layer is coplanar with a surface of the first conductive circuit layer away from the insulating layer.

6. The method of claim 1, wherein the resin is partly filled in the first spaces, thereby, a surface of the first resin layer away from the insulating layer is recessed with respect to a surface of the first conductive circuit layer away from the insulating layer.

7. The method of claim 1, wherein the first cover layer defines at least one opening to expose potions of the first conductive circuit layer.

8. The method of claim 7, wherein the first cover layer is photosensitive cover layer in a single layer, and a main composition of the photosensitive cover layer is polyurethane.

9. The method of claim 8, wherein a method for forming the first cover layer comprises:
forming a photosensitive cover layer on a surface of the first resin layer and a surface of the first conductive circuit layer away from the insulating layer, then removing portions of the photosensitive cover layer by a photolithography process, to obtain the at least one opening, and then curing the photosensitive cover layer, to obtain the first cover layer.

10. The method of claim 1, wherein the printed circuit substrate further has a second conductive circuit layer adhered on a surface of the insulating layer away from the first conductive circuit layer, and a plurality of conductive through holes electrically connected to the first conductive circuit layer and the second conductive circuit layer, the second conductive circuit layer has at least one second conductive circuit arranged as spiral-shaped, the second conductive circuit layer defines a plurality of second spaces; in the method for filling the first spaces with resin, the second spaces are also filled with resin to form a second resin layer; in the method for forming a first cover layer on a surface of the first resin layer and a surface of the first conductive circuit layer away from the insulating layer, a second cover layer is also formed on a surface of the second resin layer and a surface of the second conductive circuit layer away from the insulating layer.

11. The method of claim 1, wherein the second resin layer is made of transparent resin, a light transmittance of first resin layer is greater than about 90 percent.

12. A flexible printed circuit board used for near field communication, comprising:
an insulating layer;
a first conductive circuit layer adhered on a surface of the insulating layer, the first conductive circuit layer comprising at least one first conductive circuit arranged as spiral-shaped and defining a plurality of first spaces;
a first resin layer adhered on a surface of the insulating layer, and filling in the first spaces; and
a first cover layer adhered on a surface of the first resin layer and a surface of the first conductive circuit layer away from the insulating layer.

13. The flexible printed circuit board of claim 12, wherein the first resin layer is made of transparent resin, a light transmittance of first resin layer is greater than about 90 percent.

14. The flexible printed circuit board of claim 13, wherein the first resin layer is made of transparent ink without inorganic filler, the transparent ink without inorganic filler is consist of cycloaliphatic epoxide with a weight percentage of 28% to 34%, phenoxyl resin with a weight percentage of 10% to 20%, methylhexahydrophthalic anhydride with a weight percentage of 22% to 26%, 2-Butoxy ethanol with a weight percentage of 20% to 40%, and polyether modified polysiloxane with a weight percentage of 0.2% to 1%.

15. The flexible printed circuit board of claim 14, wherein the transparent ink without inorganic filler is consist of cycloaliphatic epoxide with a weight percentage of 31.55%, phenoxyl resin with a weight percentage of 12.62%, methylhexahydrophthalic anhydride with a weight percentage of 23.66%, 2-Butoxy ethanol with a weight percentage of 31.55%, and polyether modified polysiloxane with a weight percentage of 0.63%.

16. The flexible printed circuit board of claim 12, wherein a surface of the first resin layer away from the insulating layer is coplanar with a surface of the first conductive circuit layer away from the insulating layer.

17. The flexible printed circuit board of claim 12, wherein a surface of the first resin layer away from the insulating layer is recessed with respect to a surface of the first conductive circuit layer away from the insulating layer.

18. The flexible printed circuit board of claim 12, wherein the first cover layer defines at least one opening to expose potions of the first conductive circuit layer.

19. The flexible printed circuit board of claim 12, further comprising:
a second conductive circuit layer adhered on a surface of the insulating layer away from the first conductive circuit layer, the second conductive circuit layer having at least one second conductive circuit arranged as spiral-shaped and defining a plurality of second spaces;
a plurality of conductive through holes electrically connected to the first conductive circuit layer and the second conductive circuit layer;
a second resin layer filling in the first spaces; and
a second cover layer formed on a surface of the second resin layer and a surface of the second conductive circuit layer away from the insulating layer.

20. The flexible printed circuit board of claim 19, wherein the second resin layer is made of transparent resin, a light transmittance of first resin layer is greater than about 90 percent.
